(19) United States
(12) Patent Application Publication
(10) Pub. No.: US 2026/0104467 A1
(43) Pub. Date: Apr. 16, 2026

(54) SECONDARY BATTERY EVALUATION SYSTEM

(71) Applicant: MURATA MANUFACTURING CO., LTD., Kyoto (JP)

(72) Inventors: Koji HATTORI, Kyoto (JP); Asuki YANAGIHARA, Kyoto (JP)

(21) Appl. No.: 19/419,450

(22) Filed: Dec. 15, 2025

Related U.S. Application Data
(63) Continuation of application No. PCT/JP2024/023445, filed on Jun. 28, 2024.

(30) Foreign Application Priority Data
Jul. 4, 2023 (JP) 2023-109914

(51) Int. Cl. G01R 31/374; B60L 50/64; B60L 58/16; G01R 31/3842; H01M 10/48; H01M 50/213

(52) U.S. Cl. CPC G01R 31/374; G01R 31/3842; H01M 10/482; H01M 10/486; H01M 50/213; B60L 50/64; B60L 58/16; H01M 2220/20

(57) ABSTRACT

A secondary battery evaluation system includes a battery pack including a plurality of secondary battery cells, a voltage detection circuit that detects a terminal-to-terminal voltage value of the battery pack, a current detection circuit that detects a current value of the battery pack, a test secondary battery including at least one battery cell manufactured from the same material as the secondary battery cell, and a test power supply circuit that controls charge and discharge of the test secondary battery. The test power supply circuit sets a test charge voltage value and a test charge current value for the test secondary battery based on a terminal-to-terminal voltage value and a current value during charging of the battery pack, charges the test secondary battery with the test charge voltage value and the test charge current value, sets a test discharge voltage value and a test discharge current value for the test secondary battery based on a terminal-to-terminal voltage value and a current value during discharging of the battery pack, and discharges the test secondary battery with the test discharge voltage value and the test discharge current value to perform a simulation of charge and discharge of the battery pack. The test power supply circuit acquires SOC-OCV data of the test secondary battery by performing charge and discharge of the test secondary battery independently of driving of the battery pack at the time of measurement of SOC-OCV data.

### CROSS REFERENCE TO RELATED APPLICATIONS

The present application is a continuation of International Patent Application No. PCT/JP2024/023445, filed on Jun. 28, 2024, which claims priority to Japanese Patent Application No. 2023-109914, filed on Jul. 4, 2023, the entire content of which are incorporated herein by reference.

### BACKGROUND

The present disclosure relates to a system for evaluating degree of degradation of a secondary battery.

A battery state detection device is described in which a battery (secondary battery) that supplies power to a motor or the like of a vehicle is a battery to be evaluated for degree of degradation, and a monitoring battery for monitoring degree of degradation is connected in parallel to the battery to be evaluated for degree of degradation.

The battery state detection device detects a state of a battery to be evaluated by using the monitoring battery.

### SUMMARY

The present disclosure relates to a system for evaluating degree of degradation of a secondary battery.

However, in the battery state detection device referenced in the Background section, during an operation of the battery to be evaluated, the monitoring battery is also in operation. Therefore, during an operation of the battery to be evaluated, static evaluation such as OCV degradation analysis of the battery to be evaluated cannot be performed, and degree of degradation cannot be accurately evaluated.

Further, in a case where static evaluation such as OCV degradation analysis is performed on the battery to be evaluated, a long period of time is required. For this reason, for example, the device cannot be applied to a system, such as a battery of a UPS, whose operation cannot be stopped.

The present disclosure, in an embodiment, relates to providing a secondary battery evaluation system that accurately evaluates degree of degradation of a battery (secondary battery) to be evaluated without stopping an operation of the battery to be evaluated.

A secondary battery evaluation system of the present disclosure includes a battery pack including a plurality of secondary battery cells, a voltage detection circuit that detects a terminal-to-terminal voltage value of the battery pack, a current detection circuit that detects a current value of the battery pack, a test secondary battery including at least one battery cell manufactured from the same material as the secondary battery cell, and a power supply circuit that controls charge and discharge of the test secondary battery.

The power supply circuit sets a test charge voltage value and a test charge current value for the test secondary battery based on a terminal-to-terminal voltage value and a current value during charging of the battery pack, charges the test secondary battery with the test charge voltage value and the test charge current value, sets a test discharge voltage value and a test discharge current value for the test secondary battery based on a terminal-to-terminal voltage value and a current value during discharging of the battery pack, and discharges the test secondary battery with the test discharge voltage value and the test discharge current value to perform a simulation of charge and discharge of the battery pack. The power supply circuit acquires SOC-OCV data of the test secondary battery by performing charge and discharge of the test secondary battery independently of driving of the battery pack at the time of measurement of SOC-OCV data.

In this configuration, charge and discharge of the test secondary battery can be performed separately from driving of the battery pack. By this, also during driving of the battery pack, static evaluation of the test secondary battery can be realized. Further, since the test secondary battery is manufactured from the same material as the secondary battery cell of the battery pack, if a characteristic related to degree of degradation of the test secondary battery can be measured, a characteristic related to degree of degradation of the battery pack can be indirectly realized with high accuracy.

According to the present disclosure, in an embodiment, degree of degradation of a secondary battery to be evaluated can be accurately evaluated without stopping an operation of the secondary battery to be evaluated.

### BRIEF DESCRIPTION OF THE FIGURES

FIG. 1 is a configuration diagram illustrating an example of a power system in which a secondary battery to be evaluated is used in an embodiment of the present disclosure.

FIG. 2 is a functional block diagram illustrating an example of a secondary battery charge and discharge system including a secondary battery evaluation system according to an embodiment of the present disclosure.

FIG. 3 is a perspective view illustrating one aspect of a battery pack.

FIG. 4 is a functional block diagram illustrating an example of the secondary battery charge and discharge system including the secondary battery evaluation system according to an embodiment of the present disclosure.

FIG. 5 is a functional block diagram illustrating an example of the secondary battery evaluation system according to an embodiment of the present disclosure.

FIG. 6 is a diagram illustrating an example of a schematic configuration of an EV to which the secondary battery evaluation system is applied.

FIG. 7 is a functional block diagram illustrating an example of a battery module mounted on an EV.

FIG. 8 is a functional block diagram illustrating an example of a configuration of a test system.

### DETAILED DESCRIPTION

A secondary battery evaluation system according of the present disclosure will be described below in further detail including with reference to the drawings according to an embodiment.

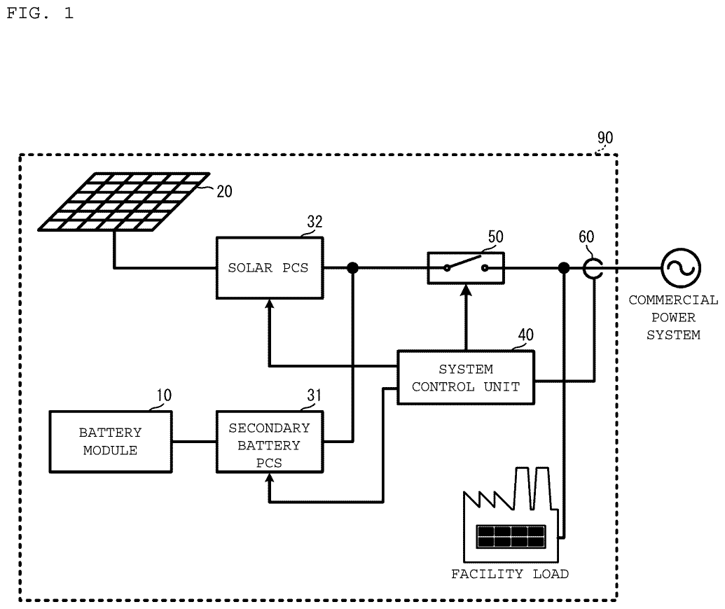

FIG. 1 is a configuration diagram illustrating an example of a power system in which a secondary battery to be evaluated is used in an embodiment of the present disclosure. As illustrated in FIG. 1, a power system 90 includes a battery module 10, a solar panel 20, a secondary battery PCS 31, a solar PCS 32, a system control unit 40, a grid interconnection relay 50, a current sensor 60, and a utility load.

Note that the power system 90 is not limited to a system in which a type of load is a utility load, and the configuration of the present disclosure can be applied to and works effectively in a system in which a secondary battery (storage battery) of the battery module 10 is driven (charged and discharged) almost continuously. Further, the power system 90 includes the solar panel 20 and the solar PCS 32, but these can be omitted.

The battery module 10 is connected to the secondary battery PCS 31. The solar panel 20 is connected to the solar PCS 32. The secondary battery PCS 31 and the solar PCS 32 are connected to the grid interconnection relay 50. The grid interconnection relay 50 is connected to a commercial power system. A current sensor 60 is disposed on a connection line between the grid interconnection relay 50 and the commercial power system.

The battery module 10 is what is called an energy storage system (ESS), and includes a plurality of secondary battery cells 111. A plurality of the secondary battery cells 111 are charged or discharged by charge and discharge control from the secondary battery PCS 31. Note that a more specific configuration of the battery module 10 will be described later.

The system control unit 40 controls an operation of the secondary battery PCS 31 and the solar PCS 32 so that power of a facility load is covered by power from the solar PCS 32 and power from the battery module 10. For example, the system control unit 40 performs control to predict power of a utility load and supply power of solar power generation and power purchased up to a contract upper limit to the utility load if power of the utility load can be covered by the power of the solar power generation and the power purchased up to the contract upper limit. At this time, the system control unit 40 controls an operation of the solar PCS 32 in a manner that power does not reversely flow to a commercial power system based on current measured by the current sensor 60.

Further, the system control unit 40 instructs the secondary battery PCS 31 to perform discharge control from the battery module 10 if power of solar power generation and power purchased up to a contract upper limit cannot cover power of a utility load and the battery module 10 is sufficiently charged.

Further, if power of solar power generation and power purchased up to a contract upper limit can cover power of a utility load and there is surplus power in the solar power generation and there is chargeable capacity in the battery module 10, the system control unit 40 instructs the secondary battery PCS 31 to perform charge control on the battery module 10.

The secondary battery PCS 31 performs charge and discharge control of a plurality of the secondary battery cells 111 of the battery module 10 based on an instruction from the system control unit 40.

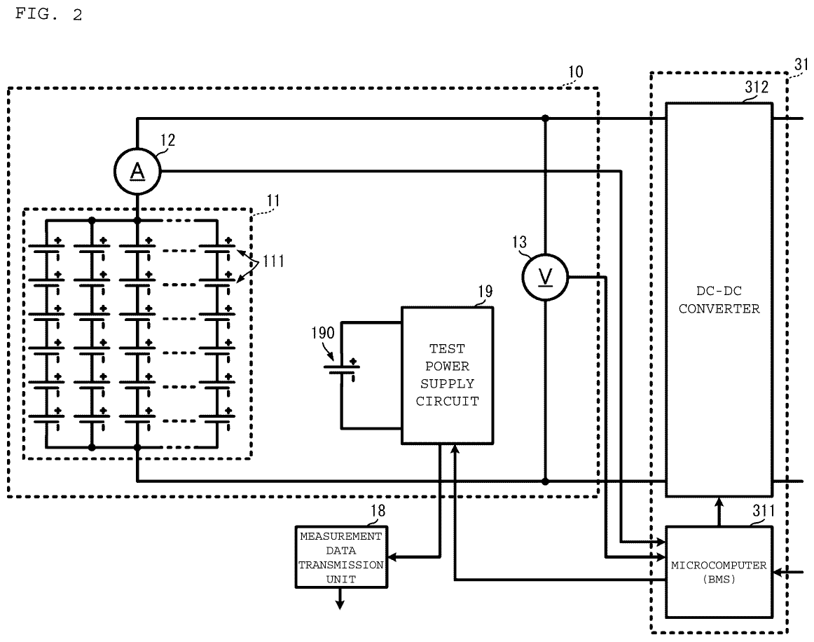

FIG. 2 is a functional block diagram illustrating an example of a secondary battery charge and discharge system including the secondary battery evaluation system according to the first embodiment of the present disclosure. As illustrated in FIG. 2, the secondary battery charge and discharge system includes the battery module 10 and the secondary battery PCS 31.

The secondary battery PCS 31 includes a microcomputer 311 and a DC-DC converter 312. The battery module 10 includes a battery pack 11, a current detection circuit 12, a voltage detection circuit 13, a test power supply circuit 19, and a test secondary battery 190.

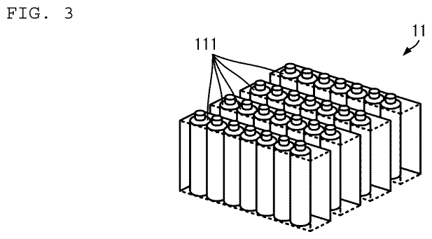

The battery pack 11 is configured by connecting a plurality of the secondary battery cells 111 in series and in parallel. FIG. 3 is a perspective view illustrating one aspect of the battery pack. A plurality of the secondary battery cells 111 are put together in a two-dimensional arrangement as shown in FIG. 3, for example, to constitute the battery pack 11.

A positive electrode terminal and a negative electrode terminal of the battery pack 11 are connected to the DC-DC converter 312 of the secondary battery PCS 31.

The current detection circuit 12 is connected between a positive electrode terminal of the battery pack 11 and the DC-DC converter 312. An output terminal of the current detection circuit 12 is connected to the microcomputer 311. By this, the microcomputer 311 can acquire a current value of the battery pack 11.

The voltage detection circuit 13 is connected between a positive electrode terminal and a negative electrode terminal of the battery pack 11. An output terminal of the voltage detection circuit 13 is connected to the microcomputer 311. By this, the microcomputer 311 can acquire a terminal-to-terminal voltage value of the battery pack 11. The voltage detection circuit 13 may be configured to individually detect cell voltage of each of a plurality of secondary battery cells in a battery pack, and output a total value of the cell voltage as terminal-to-terminal voltage of the battery pack 11.

The microcomputer 311 performs charge and discharge control of the DC-DC converter 312 in response to operation control from the system control unit 40. At this time, the microcomputer 311 performs charge and discharge control based on a current value from the current detection circuit 12 and a voltage value from the voltage detection circuit 13.

The test secondary battery 190 is made from the same material as a plurality of the secondary battery cells 111. That is, the test secondary battery 190 is the same as one of the secondary battery cells 111. Note that the test secondary batteries 190 may be composed of a plurality of the secondary battery cells 111 if the number of the test secondary batteries 190 is smaller than the number of the secondary battery cells 111 constituting the battery pack 11. However, the number is preferably small. By this, a configuration of the test secondary battery 190 can be simplified, and downsizing and cost reduction can be realized.

A positive electrode terminal and a negative electrode terminal of the test secondary battery 190 are connected to the test power supply circuit 19.

The test power supply circuit 19 includes a charge circuit and an electronic load. The test power supply circuit 19 performs charge control of the test secondary battery 190 by the charge circuit. The test power supply circuit 19 performs discharge control of the test secondary battery 190 by an electronic load.

The test power supply circuit 19 is connected to the microcomputer 311 of the secondary battery PCS 31 and a measurement data transmission unit 18. The measurement data transmission unit 18 may be disposed inside or outside the battery module 10.

The test power supply circuit 19 acquires a charge condition (charge current value and charge voltage value) of the battery pack 11 from the microcomputer 311. The test power supply circuit 19 sets a charge voltage value and a charge current value per unit cell of a plurality of the secondary battery cells 111 constituting the battery pack 11 to be the same as a test charge voltage value and a test charge current value per unit cell of the test secondary battery 190.

For example, the test charge voltage value is set by dividing a terminal-to-terminal voltage value of the battery pack 11 during charging by the number of the secondary battery cells 111 connected in series in the battery pack 11.

For example, the test charge current value is set by dividing a current value of the battery pack 11 during charging by the number of the secondary battery cells 111 connected in parallel in the battery pack 11.

The test power supply circuit 19 performs charge control of the test secondary battery 190 based on a test charge voltage value and a test charge current value.

The test power supply circuit 19 acquires a discharge condition (discharge current value and discharge voltage value) of the battery pack 11 from the microcomputer 311. The test power supply circuit 19 sets a discharge voltage value and a discharge current value of a plurality of the secondary battery cells 111 constituting the battery pack 11 to be the same as a test discharge voltage value and a test discharge current value of the test secondary battery 190.

For example, the test discharge voltage value is set by dividing a terminal-to-terminal voltage value of the battery pack 11 during discharging by the number of the secondary battery cells 111 connected in series in the battery pack 11.

For example, the test discharge current value is set by dividing a current value of the battery pack 11 during discharging by the number of the secondary battery cells 111 connected in parallel in the battery pack 11.

The test power supply circuit 19 performs discharge control of the test secondary battery 190 based on a test discharge voltage value and a test discharge current value.

By performing such simulated charge and discharge, the secondary battery evaluation system of the present embodiment can make degree of degradation of the test secondary battery 190 the same as degree of degradation of the secondary battery cell 111 constituting the battery pack 11.

When SOC-OCV data is measured, the test power supply circuit 19 temporarily stops simulation of charge and discharge of the battery pack 11 described above.

The test power supply circuit 19 stores a SOC-OCV measurement condition in advance.

Prior to SOC-OCV measurement, the test power supply circuit 19 discharges the test secondary battery 190 to a fully discharged state (SOC 0%). After the above, intermittent charge for SOC-OCV measurement is performed, and SOC-OCV data (charge capacity and open circuit voltage) up to a fully charged state (SOC 100%) is measured.

Specifically, after the test secondary battery 190 is charged with predetermined current for predetermined time (for example, 1 minute at 1 C) from a fully discharged state (SOC 0%), relaxation time (for example, 10 minutes) for stabilizing increased terminal voltage is inserted, and terminal voltage after reaching an equilibrium state is measured as OCV data, and this procedure is repeated until the test secondary battery 190 is fully charged. This makes it possible to acquire SOC-OCV data indicating how an OCV value changes with a change in SOC.

The test power supply circuit 19 outputs the measured SOC-OCV data to the measurement data transmission unit 18. The measurement data transmission unit 18 transmits the SOC-OCV data to an external device or the like for degradation degree analysis.

By this, the secondary battery evaluation system of the present embodiment can acquire SOC-OCV data of the test secondary battery 190 without stopping drive (charge and discharge) of the battery pack 11, and can realize OCV analysis of the test secondary battery 190.

At this time, as described above, degree of degradation of the test secondary battery 190 accurately simulates degree of degradation of the secondary battery cell 111 of the battery pack 11. Therefore, OCV analysis of the secondary battery cell 111 of the battery pack 11 can be accurately performed by performing OCV analysis of the test secondary battery 190. By this, degree of degradation of the secondary battery cell 111 of the battery pack 11 can be accurately evaluated.

Note that when the measurement of SOC-OCV data ends, the test power supply circuit 19 acquires a state of charge of the battery pack 11 from the microcomputer 311, and resumes the simulation of charge and discharge of the battery pack 11. Then, at a next SOC-OCV data measurement timing, the test power supply circuit 19 performs the measurement of SOC-OCV data described above. Hereinafter, simulation of charge and discharge of the battery pack 11 and measurement of SOC-OCV data are repeated.

By this, the secondary battery evaluation system of the present embodiment can continuously and accurately evaluate degree of degradation of the battery pack 11 (the secondary battery cells 111 of the battery pack 11).

Further, in the above configuration, the test secondary battery 190 is disposed in the battery module 10 as in the battery pack 11. By this, an operation environment of the test secondary battery 190 is similar to an operation environment (environmental temperature) of the battery pack 11. Therefore, simulation accuracy of degree of degradation of the secondary battery cell 111 of the battery pack 11 using the test secondary battery 190 is improved. As a result, the secondary battery evaluation system of the present embodiment can further accurately evaluate degree of degradation of the battery pack 11 (the secondary battery cells 111 of the battery pack 11).

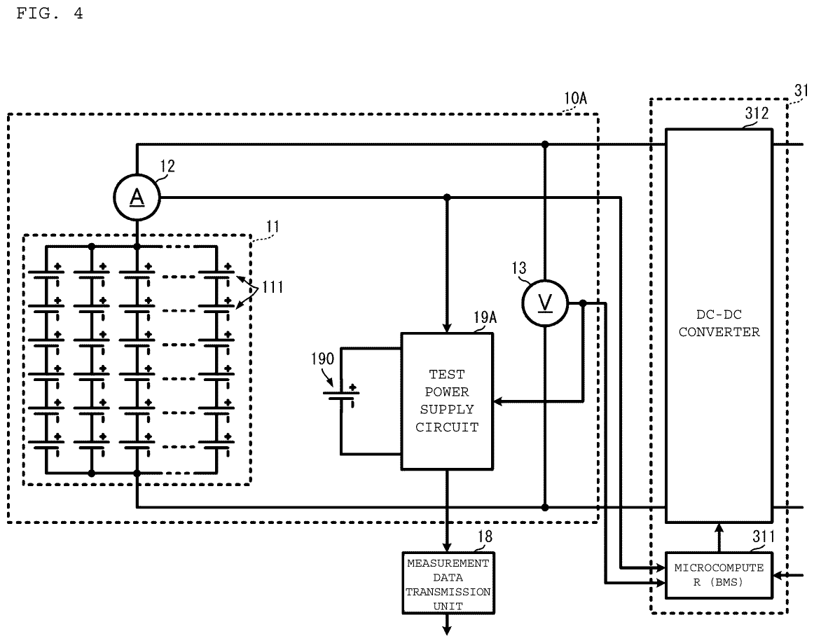

The secondary battery evaluation system according to a second embodiment of the present disclosure will be described with reference to the drawings. FIG. 4 is a functional block diagram illustrating an example of the secondary battery charge and discharge system including the secondary battery evaluation system according to the second embodiment of the present disclosure.

The secondary battery evaluation system according to the second embodiment is different from the secondary battery evaluation system according to the first embodiment in that the secondary battery evaluation system according to the second embodiment does not use the microcomputer 311 of the secondary battery PCS 31 while the secondary battery evaluation system according to the first embodiment uses the microcomputer 311. Other configurations of the secondary battery evaluation system according to the second embodiment are the same as those of the secondary battery evaluation system according to the first embodiment, and description of the same parts will be omitted.

The secondary battery evaluation system includes a battery module 10A. The battery module 10A is different from the battery module 10 according to the first embodiment in a test power supply circuit 19A. Other configurations of the battery module 10A are the same as those of the battery module 10, and description of the same parts will be omitted.

The test power supply circuit 19A is connected to an output terminal of the current detection circuit 12 and an output terminal of the voltage detection circuit 13. The test power supply circuit 19A directly acquires a current value of the battery pack 11 from the current detection circuit 12. The test power supply circuit 19A directly acquires a terminal-to-terminal voltage value of the battery pack 11 from the voltage detection circuit 13.

By this, the secondary battery evaluation system of the present embodiment can accurately measure SOC-OCV data for evaluating degree of degradation of the battery pack 11 (the secondary battery cell 111 of the battery pack 11) only with the battery module 10A without including the microcomputer 311 of the secondary battery PCS 31.

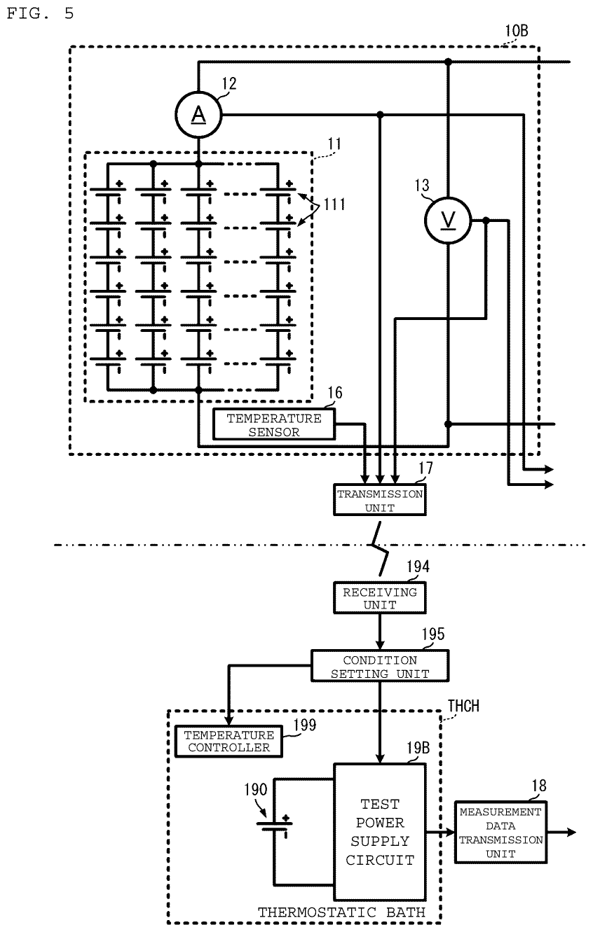

The secondary battery evaluation system according to a third embodiment of the present disclosure will be described with reference to the drawings. FIG. 5 is a functional block diagram illustrating an example of the secondary battery evaluation system according to the third embodiment of the present disclosure.

The secondary battery evaluation system according to the third embodiment is different from the secondary battery evaluation system according to the second embodiment in that a test power supply circuit 19B, the test secondary battery 190, and the like are disposed at different portions from a battery module 10B. Hereinafter, only parts where the secondary battery evaluation system according to the third embodiment is different from the secondary battery evaluation system according to the second embodiment will be described, and description of same parts will be omitted.

The battery module 10B includes the battery pack 11, the current detection circuit 12, the voltage detection circuit 13, and a temperature sensor 16. That is, the battery module 10B does not include the test power supply circuit 19B and the test secondary battery 190.

The temperature sensor 16 detects an ambient temperature of the battery pack 11 and outputs the ambient temperature to a transmission unit 17. The current detection circuit 12 outputs a current value of the battery pack 11 to the transmission unit 17. The voltage detection circuit 13 outputs a voltage value of the battery pack 11 to the transmission unit 17.

The transmission unit 17 transmits an ambient temperature, a current value, and a voltage value to a receiving unit 194.

The receiving unit 194, a condition setting unit 195, the test power supply circuit 19B, the test secondary battery 190, and the measurement data transmission unit 18 are disposed in different places from the battery module 10B. For example, these are disposed at a test site or the like where the user or the like who performs OCV analysis is present.

The test power supply circuit 19B and the test secondary battery 190 are disposed in a thermostatic bath THCH. A temperature controller 199 is installed in the thermostatic bath THCH. The temperature controller 199 adjusts a temperature of the thermostatic bath THCH.

The receiving unit 194 outputs an ambient temperature, a current value, and a voltage value to the condition setting unit 195. The condition setting unit 195 outputs an ambient temperature to the temperature controller 199, and outputs a current value and a voltage value to the test power supply circuit 19B.

The temperature controller 199 performs temperature adjustment of the thermostatic bath THCH so as to have the same temperature environment as the received ambient temperature.

The test power supply circuit 19B simulates charge and discharge of the battery pack 11 with respect to the test secondary battery 190 based on the received current value and voltage value. Further, the test power supply circuit 19B performs measurement of SOC-OCV data at a predetermined timing.

As described above, with the configuration of the present embodiment, OCV analysis and evaluation of degree of degradation can be performed without disposing the test secondary battery 190 in the vicinity of the battery pack 11 to be evaluated. By this, evaluation can be readily assigned to an expert in OCV analysis at a remote place. For example, a battery manufacturer can evaluate, with high accuracy, degree of degradation of an ESS battery (the battery pack 11) operated by a customer by a system in which the test secondary battery 190 is placed in the battery manufacturer, without the need to visit the customer's site where an ESS is operated.

Note that, in the above description, a factory or the like is assumed, but the secondary battery evaluation system of the present application can also be applied to evaluation of a secondary battery (EV battery) such as an EV (electric vehicle) that uses electricity as driving energy.

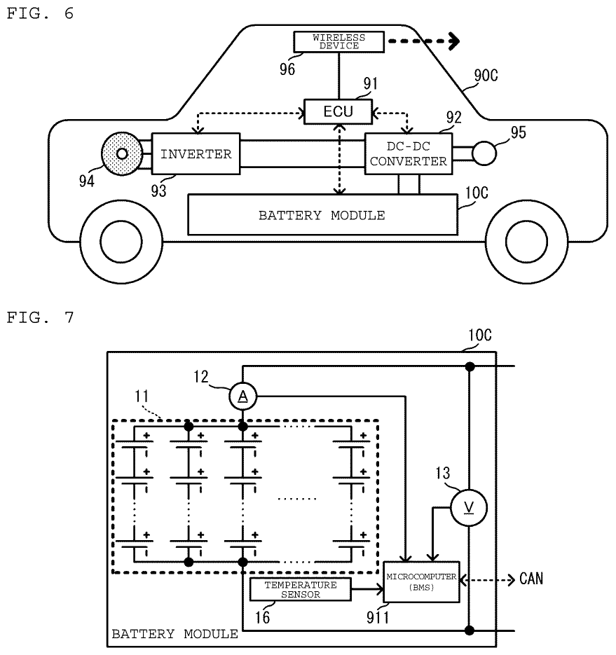

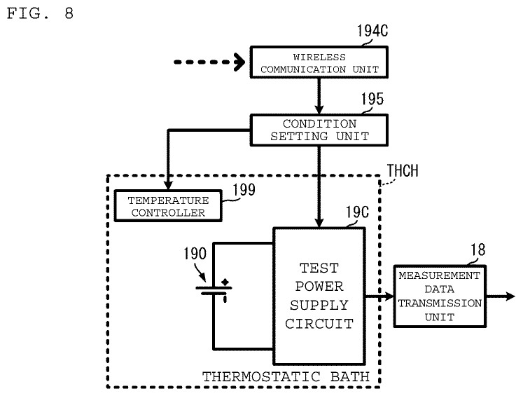

FIG. 6 is a diagram illustrating an example of a schematic configuration of an EV to which the secondary battery evaluation system is applied. FIG. 7 is a functional block diagram illustrating an example of a battery module mounted on an EV. FIG. 8 is a functional block diagram illustrating an example of a configuration of a test system. Note that functional units having the same configuration as those of the above-described embodiments are denoted by the same reference numeral, and description of parts denoted by the same reference numerals will be omitted below.

As illustrated in FIG. 6, an EV 90C includes an ECU 91, a DC-DC converter 92, an inverter 93, a drive motor 94, a charging port 95, a wireless device 96, and a battery module 10C.

As illustrated in FIG. 7, the battery module 10C includes the battery pack 11, the current detection circuit 12, the voltage detection circuit 13, the temperature sensor 16, and the microcomputer 911.

The ECU 91, the DC-DC converter 92, the inverter 93, and the microcomputer 911 of the battery module 10C are connected to a CAN. The ECU 91 issues a control command to the DC-DC converter 92, the inverter 93, and the battery module 10C through the CAN, and performs overall control of the EV 90C.

The DC-DC converter 92 is connected to the charging port 95 and is connected to the inverter 93. The inverter 93 is connected to the drive motor 94.

The DC-DC converter 92 converts DC power supplied from the charging port 95 into charge voltage and charge current of the battery pack 11 of the battery module 10C, and supplies charge power of the battery pack 11 of the battery module 10C.

Further, the DC-DC converter 92 converts DC power stored in the battery pack 11 into a DC voltage for an inverter and a DC voltage, and supplies the DC voltage to the inverter 93.

The inverter 93 converts DC current and DC voltage supplied through the DC-DC converter 92 into predetermined AC voltage and AC current, and supplies the AC voltage and the AC current to the drive motor 94.

The wireless device 96 transmits an ambient temperature, a current value, and a voltage value acquired through the microcomputer 911 and the ECU 91 to a wireless communication unit 194C arranged in the thermostatic bath THCH located at a position different from the EV 90C.

By this, measurement of SOC-OCV data using the thermostatic bath THCH as described in the third embodiment can be performed.

The present disclosure is described below in further detail according to an embodiment.
<1> A secondary battery evaluation system including:
a battery pack including a plurality of secondary battery cells;
a voltage detection circuit that detects a terminal-to-terminal voltage value of the battery pack;
a current detection circuit that detects a current value of the battery pack;
a test secondary battery including at least one battery cell manufactured from a same material as the secondary battery cell; and
a power supply circuit that controls charge and discharge of the test secondary battery,
in which
the power supply circuit:
   sets a test charge voltage value and a test charge current value for the test secondary battery based on the terminal-to-terminal voltage value and the current value during charging of the battery pack, and charges the test secondary battery with the test charge voltage value and the test charge current value,
   sets a test discharge voltage value and a test discharge current value for the test secondary battery based on the terminal-to-terminal voltage value and the current value during discharging of the battery pack, and discharges the test secondary battery with the test discharge voltage value and the test discharge current value to perform a simulation of charge and discharge of the battery pack, and
   acquires SOC-OCV data of the test secondary battery by performing charge and discharge of the test secondary battery independently of driving of the battery pack at the time of measurement of SOC-OCV data.
<2> The secondary battery evaluation system according to <1>, in which the test secondary battery is disposed in a battery module incorporating the battery pack.
<3> The secondary battery evaluation system according to <1> or <2>, further including:
a temperature sensor that detects an ambient temperature of the battery pack;
a transmission unit that transmits the terminal-to-terminal voltage value, the current value, and the ambient temperature;
a receiving unit that receives the terminal-to-terminal voltage value, the current value, and the ambient temperature of the battery pack from the transmission unit; and
a thermostatic bath,
in which
the battery pack, the voltage detection circuit, the current detection circuit, the temperature sensor, and the transmission unit are disposed at a first place,
the test secondary battery, the power supply circuit, the receiving unit, and the thermostatic bath are disposed at a second place different from the first place,
the test secondary battery is disposed in the thermostatic bath, and
the thermostatic bath is controlled to reproduce the ambient temperature of the battery pack.
<4> The secondary battery evaluation system according to <3>, in which the battery pack is a battery for driving an electric vehicle.

### DESCRIPTION OF REFERENCE SYMBOLS

10, 10A, 10B, 10C: Battery module
11: Battery pack
12: Current detection circuit
13: Voltage detection circuit
16: Temperature sensor
17: Transmission unit
18: Measurement data transmission unit
19, 19A, 19B: Test power supply circuit
20: Solar panel
31: Secondary battery PCS
32: Solar PCS
40: System control unit
50: Grid interconnection relay
60: Current sensor
90: Power system
90C: EV
91: ECU
92: DC-DC converter
93: Inverter
94: Drive motor
95: Charging port
96: Wireless device
111: Secondary battery cell
190: Test secondary battery
194: Receiving unit
194C: Wireless communication unit
195: Condition setting unit
199: Temperature controller
311: Microcomputer
312: DC-DC converter
911: Microcomputer
THCH: Thermostatic bath

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A secondary battery evaluation system comprising:
a battery pack including a plurality of secondary battery cells;
a voltage detection circuit that detects a terminal-to-terminal voltage value of the battery pack;
a current detection circuit that detects a current value of the battery pack;
a test secondary battery including at least one battery cell manufactured from a same material as the secondary battery cell; and
a power supply circuit that controls charge and discharge of the test secondary battery,
wherein
the power supply circuit:
sets a test charge voltage value and a test charge current value for the test secondary battery based on the terminal-to-terminal voltage value and the current value during charging of the battery pack, and charges the test secondary battery with the test charge voltage value and the test charge current value,
sets a test discharge voltage value and a test discharge current value for the test secondary battery based on the terminal-to-terminal voltage value and the current value during discharging of the battery pack, and discharges the test secondary battery with the test discharge voltage value and the test discharge current value to perform a simulation of charge and discharge of the battery pack, and
acquires SOC-OCV data of the test secondary battery by performing charge and discharge of the test secondary battery independently of driving of the battery pack at a time of measurement of SOC-OCV data.

2. The secondary battery evaluation system according to claim 1, wherein
the test secondary battery is disposed in a battery module incorporating the battery pack.

3. The secondary battery evaluation system according to claim 1, further comprising:
a temperature sensor that detects an ambient temperature of the battery pack;
a transmission unit that transmits the terminal-to-terminal voltage value, the current value, and the ambient temperature;
a receiving unit that receives the terminal-to-terminal voltage value, the current value, and the ambient temperature of the battery pack from the transmission unit; and
a thermostatic bath,
wherein
the battery pack, the voltage detection circuit, the current detection circuit, the temperature sensor, and the transmission unit are disposed at a first place,
the test secondary battery, the power supply circuit, the receiving unit, and the thermostatic bath are disposed at a second place different from the first place,
the test secondary battery is disposed in the thermostatic bath, and
the thermostatic bath is controlled to reproduce the ambient temperature of the battery pack.

4. The secondary battery evaluation system according to claim 3, wherein the battery pack is a battery for driving an electric vehicle.
